(19) United States
(12) Patent Application Publication
(10) Pub. No.: US 2026/0236652 A1
(43) Pub. Date: Aug. 13, 2026

(54) GENERATING A TILED REGISTER TRANSFER LEVEL DESIGN

(71) Applicant: Baya Systems, Inc., Santa Clara, CA (US)

(72) Inventors: Aditya Gurjar, San Jose, CA (US); Eric Norige, Santa Clara, CA (US); Narayana Sri Harsha Gade, Bangalore (IN)

(21) Appl. No.: 19/173,622

(22) Filed: Apr. 8, 2025

(30) Foreign Application Priority Data
Feb. 13, 2025 (IN) 202511012390

(51) Int. Cl. G06F 30/327; G06F 16/901

(52) U.S. Cl. CPC G06F 30/327; G06F 16/9024

(57) ABSTRACT

A method for generating a tiled Register Transfer Level (RTL) design includes determining a number of identification bits required to uniquely identify each instance within the tiled RTL design, utilizing local bits for local identification, context bits for contextual distinction, and parent bits for hierarchical association. Further, the method includes identifying groups of edges within the RTL design graph to uniquely allocate the local identifier and context identifier for generating the tiled RTL design. The generation process incorporates the parent bits from a boundary port of the RTL design, along with the assignment of the local bits and the context bits to child RTL instances.

### CROSS-REFERENCE TO RELATED APPLICATIONS

This application claims priority to IN 202511012390, filed on February 13, 2025, the contents of which are incorporated herein by reference.

### BACKGROUND

### Technical Field

Methods and example embodiments described herein are generally directed to the generation of a tiled Register Transfer Level (RTL) design, and more specifically, to generating an optimized instance identity (ID) for strap compression.

### Related Art

The number of components on a chip is rapidly growing due to increasing levels of integration, system complexity, and shrinking transistor geometry. Complex System-on-Chips (SoCs) may involve a variety of components e.g., processor cores, Digital Signal Processors (DSPs), hardware accelerators, memory, and Input/Output (I/O) interfaces, while Chip Multi-Processors (CMPs) may involve a large number of homogenous processor cores, memory, and I/O subsystems. In both systems, the on-chip interconnect plays a key role in providing high-performance communication between the various components. Due to scalability limitations of traditional buses and crossbar-based interconnects, Network-on-Chip (NoC) has emerged as a paradigm to interconnect a large number of components on the chip.

The NoC is a global shared communication infrastructure made up of several routing nodes interconnected with each other using point-to-point physical links. Messages are injected by source components and are routed from the source components to a destination component over multiple intermediate nodes and physical links. The destination component then ejects the message and provides it to other components associated with the destination component. For the remainder of the document, the terms ‘processing elements,’ ‘components,’ ‘blocks,’ ‘hosts,’ or ‘cores,’ will be used interchangeably to refer to the various system components which are interconnected using a NoC. The terms ‘routers’ and ‘nodes’ will also be used interchangeably. Without loss of generalization, the system with multiple interconnected components will itself be referred to as a ‘multi-core system’.

There are several possible topologies in which the routers can connect to one another to create the system network. Bi-directional rings 100A (as shown in FIG. 1(A)) and 2-D mesh 100B (as shown in FIG. 1(B)) are examples of topologies in the related art.

Packets are message transport units for intercommunication between various components. Routing involves identifying a path which is a set of routers and physical links of the network over which packets are sent from a source to a destination. Components are connected to one or multiple ports of one or multiple routers; with each such port having a unique identifier (ID). Packets carry the destination’s router and port ID for use by the intermediate routers to route the packet to the destination component.

Examples of routing techniques include deterministic routing, which involves choosing the same path from A to B for every packet. This form of routing is oblivious to the state of the network and does not load balance across path diversities which may exist in the underlying network. However, such deterministic routing may be simple to implement in hardware, maintains packet ordering, and may be easy to make free of network-level deadlocks. Shortest path routing minimizes the latency as it reduces the number of hops from the source to the destination. For this reason, the shortest path is also the lowest power path for communication between the two components. Dimension-order routing is a form of deterministic shortest-path routing in 2D mesh networks.

FIG. 2 illustrates an example of XY routing in a two-dimensional mesh 200. More specifically, FIG. 2 illustrates XY routing from node ‘34’ to node ‘00’. In the example of FIG. 2, each component is connected to only one port of one router. A packet is first routed in the X dimension till the packet reaches node ‘04’ where the x dimension is the same as the destination. The packet is next routed in the Y dimension until the packet reaches the destination node.

Source routing and routing using tables are other routing options used in NoC. Adaptive routing can dynamically change the path taken between two points on the network based on the state of the network. This form of routing may be complex to analyze and implement and is therefore rarely used in practice.

The NoC may contain multiple physical networks. Over each physical network, there may exist multiple virtual networks, where different message types are transmitted over different virtual networks. In this case, at each physical link or channel, there are multiple virtual channels (VCs), and each VC may have dedicated buffers at both endpoints. In any given clock cycle, only one VC can transmit data on the physical channel.

NoC interconnects often employ wormhole routing, where a large message or packet is broken into small pieces known as flits (also referred to as flow control digits). The first flit is the header flit which holds information about the packet’s route and key message level information along with payload data and sets up the routing behavior for all subsequent flits associated with the message. Zero or more body flits follow the head flit, containing the remaining payload of data. The final flit is a tail flit which in addition to containing the last payload also performs some bookkeeping to close the connection for the message. In wormhole flow control, VCs are often implemented.

The physical channels are time-sliced into a number of independent logical channels, i.e. VCs. VCs provide multiple independent paths to route packets; however, they are time-multiplexed on the physical channels. A VC holds the state needed to coordinate the handling of the flits of a packet over a channel. At a minimum, this state identifies the output channel of the current node for the next hop of the route and the state of the virtual channel (idle, waiting for resources, or active). The VC may also include pointers to the flits of the packet that are buffered on the current node and the number of flit buffers available on the next node.

The term “wormhole” refers to the way messages are transmitted over the channels: the output port at the next router can be so short that received data can be translated in the head flit before the full message arrives. This allows the router to quickly set up the route upon arrival of the head flit and then opt-out from the rest of the conversation. Since a message is transmitted flit by flit, the message may occupy several flit buffers along its path at different routers, creating a worm-like image.

Based on the traffic between various endpoints, and the routes and physical networks that are used for various messages, different physical channels of the NoC interconnect may experience different levels of load and congestion. The capacity of various physical channels of a NoC interconnect is determined by the width of the channel (number of physical wires) and the clock frequency at which it is operating. Various channels of the NoC may operate at different clock frequencies. However, all channels are equal in width or number of physical wires. This width can be determined based on the most loaded channel and the clock frequency of various channels.

When a component or subsystem design is instantiated multiple times in the larger design, we call that tiling. This is usually done to reduce the cost of finalizing the physical design of different regions of the chip by duplicating the design of one region into others. Often, a tiled component needs to exhibit different behavior in different instances. For example, a tiled router may need to compute different output ports for the same routing information based on which instance that routing information arrives at. As the circuit implementing that functionality is part of the design and must be shared across all instances, the difference in behavior is often implemented using “straps”. These are additional primary inputs of the logic of the component that are connected to a fixed value for each instance. These values can vary from instance to instance, allowing different behavior of the instances to be triggered by different strap values applied to them.

Component designs may have a large number of strap bits that configure their behavior differently from instance to instance. Logic can be added to the component definition that expands from a short instance identifier to the specific pattern of strap bits needed on that instance. Adding this logic can make synthesis more efficient, such as if all instances have the same value of a configuration bit, the logic can be specialized to assume that configuration bit has that value, instead of needing to be able to work for any value of that configuration bit. It can also simplify the complexity of setting strap values when integrating RTL from multiple sources.

### SUMMARY

Aspects of the example implementations may include a method for generating a tiled register transfer level (RTL) design, the method including determining a number of identification bits to identify each RTL instance with local bits corresponding to a local identifier, context bits corresponding to a context identifier, and parent bits corresponding to a parent identifier. Further, the method includes identifying first groups of edges of a graph representation of the RTL design to assign the local identifier uniquely by edge and second groups of edges of the graph representation of the RTL design to assign the context identifier uniquely by group, and generating the tiled RTL design with the parent bits coming from a boundary port of the RTL design, and the local bits and the context bits provided to the child RTL instances as assigned.

Additional aspects of the example implementations may include a computer-readable storage medium storing instructions for generating a tiled RTL design, the instruction including determining a number of identification bits to identify each RTL instance with local bits corresponding to a local identifier, context bits corresponding to a context identifier, and parent bits corresponding to a parent identifier. Further, the instruction includes identifying first groups of edges of a graph representation of the RTL design to assign the local identifier uniquely by edge and second groups of edges of the graph representation of the RTL design to assign the context identifier uniquely by group and generating the tiled RTL design with the parent bits coming from a boundary port of the RTL design, and the local bits and the context bits provided to the child RTL instances as assigned.

### BRIEF DESCRIPTION OF THE DRAWINGS

FIGS. 1(A) and 1(B) illustrate examples of Bidirectional ring and 2D Mesh Network on Chip (NoC) topologies.

FIG. 2 illustrates an example of XY routing in a NoC having a two-dimensional mesh topology.

FIGS. 3A and 3B illustrate schematic representations of a requirement of distinct configurations for each instance in a same design.

FIG. 4 illustrates a flowchart of a method for generating a tiled Register Transfer Level (RTL) design, in accordance with an example implementation.

FIG. 5 illustrates a schematic representation of a configuration mechanism, in accordance with an example implementation.

FIG. 6A illustrates a schematic representation of a tiled RTL design, in accordance with an example implementation.

FIG. 6B illustrates a hierarchical RTL design, in accordance with an example implementation.

FIG. 6C illustrates a Directed Acyclic Graph (DAG) representation of the tiled RTL design, in accordance with an example implementation.

FIG. 7 illustrates a schematic representation of the hierarchical RTL design structure, in accordance with an example implementation.

FIG. 8 illustrates a computer/server block diagram upon which the example implementations described herein may be implemented.

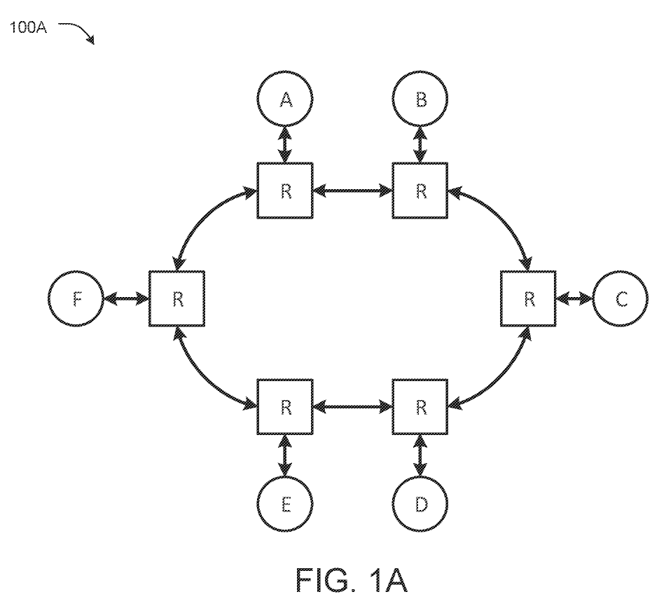

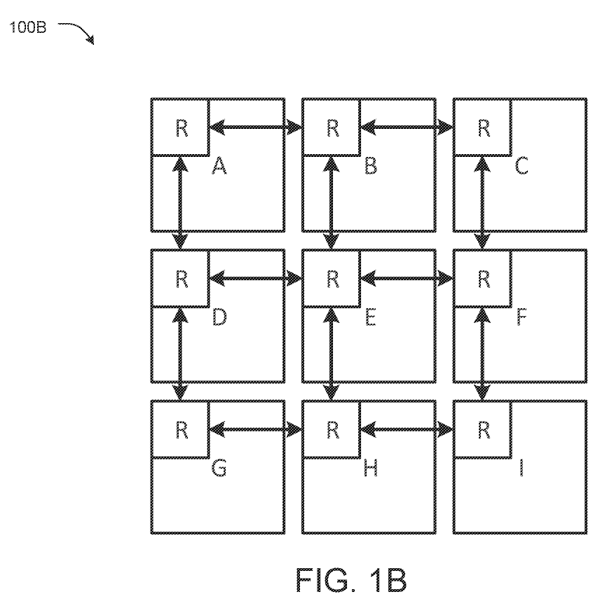

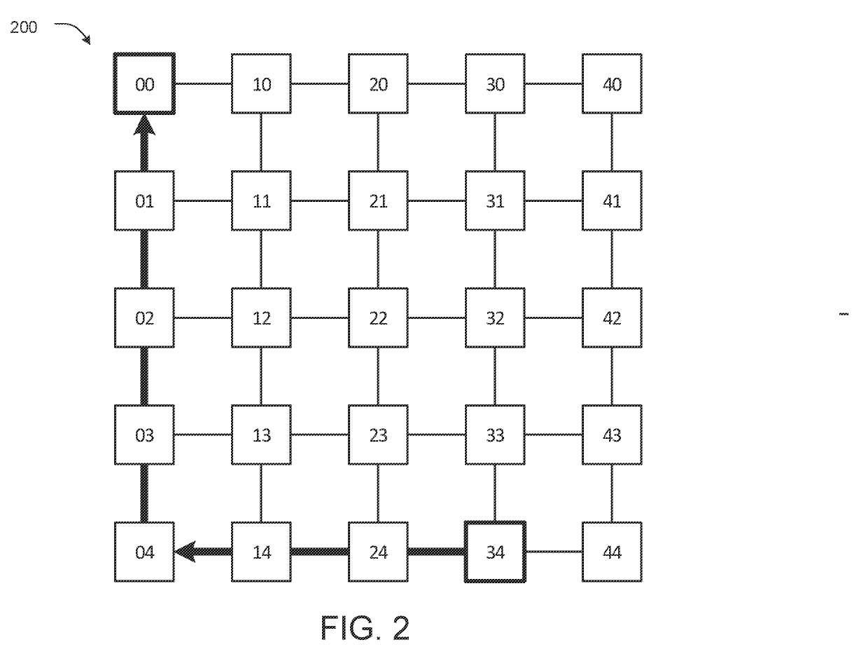

### DETAILED DESCRIPTION

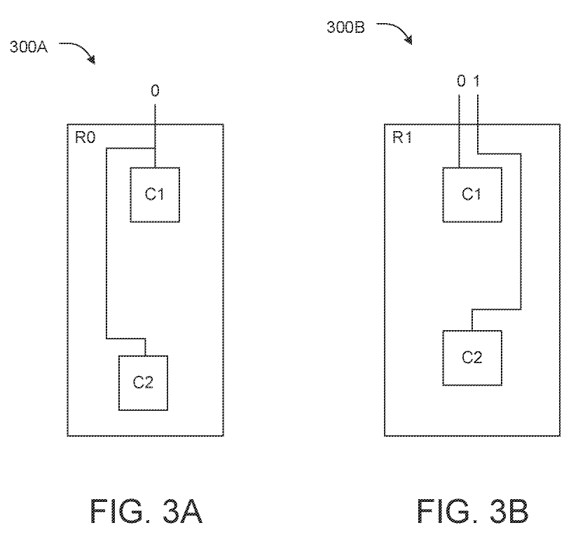

In existing methods for creating Register Transfer Level (RTL) designs and tiled RTL designs, a large number of strap identifier bits could be needed on the boundary of tiled submodules that themselves contain tiled components. The existing methods often face challenges in assigning instance identities (IDs) while considering the hierarchical structure of a Network on Chip (NoC) system or other digital systems. If component identifiers are assigned without considering the global structure of the design, different instances of the same submodule may need unique instance ids for the components within that submodule, requiring additional strap compression at the submodule level or a large number of straps at the boundary of the submodule. For example, FIGS. 3A and 3B illustrate schematic representations 300A and 300B of a requirement of distinct configurations for each instance in a same design. Referring to FIGS. 3A, and 3B, each instance requires a distinct configuration in a parent region (R0 and R1)). Therefore, the existing methods have certain limitations and opportunities for improvement in the configuration process. The challenge begins with the observation that, although there are two instances (C1 and C2) of the design, each one demands unique configuration settings due to a specific role or position within the system. In the current setup, there is only a single expansion table available for both instances (C1 and C2), mapping instance IDs to configurations. Thus, the existing methods are inadequate, as each instance typically needs specific configuration parameters to meet individual design requirements. The expansion tables are generally used to translate instance IDs into configuration bits (0 and 1) that manage different functional aspects of the design, having just one expansion table restricts the ability to tailor configurations for each instance. Furthermore, inefficiencies arise due to the excessive number of configuration bits (0 and 1), known as “strap bits”, which can be exposed at the boundary, as represented in FIG. 3B. The strap bits define settings or features applied across the different instances (C1 and C2) of the design, but managing the bits is labor-intensive. Handling the bits manually increases the risk of inconsistencies across instances. This description emphasizes the need for a more flexible and efficient configuration process to accommodate the unique requirements of each design instance. Moreover, the existing methods for configuring hardware components often include designing separate hardware for each possible configuration. In the conventional method(s), each configuration requires dedicated circuitry, leading to increased complexity, larger chip sizes, and potentially higher manufacturing costs.

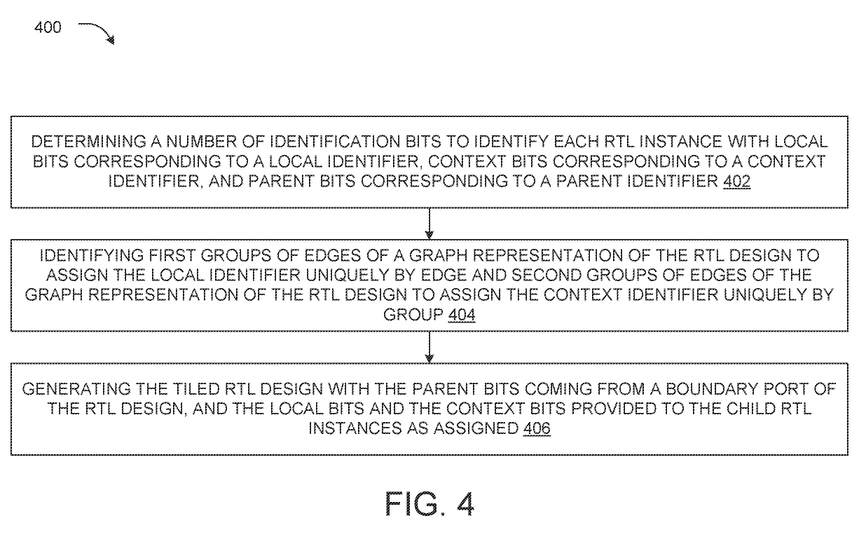

Unlike the existing method(s), the present disclosure includes a method for generating an efficient hierarchically-tiled RTL design. Instead of configuring dedicated hardware for each configuration as per the existing method(s), components may be designed to be configurable through a set of pre-defined strap values and control bits. This method may provide multiple configurations to share the same circuitry, resulting in a more compact design and optimized use of resources. The method may include a strap compression technique that replaces many strap bits needed by a module with an instance identifier and a decompression function to translate that identifier into the strap values needed for that instance. Further, the method may assign local and context identifiers to edges and groups of edges within an RTL design graph for the purpose of assigning identification bits to each RTL instance. These identification bits may include local, context, and parent identifiers. The tiled RTL design may be generated using parent bits that are primary inputs to a parent design and are broadcast via wires to any child RTL instances within that parent that need strap identifiers. Various embodiments of the present disclosure will be explained in detail with respect to FIGS. 4-7.

In the present disclosure, the method is related to generation of a tiled RTL design. In digital systems, RTL is a level of abstraction designed to represent a flow of data between registers/flops and the logical operations performed on that data. At the RTL level, the behavior of the system (e.g., a digital system) may be represented in terms of the transfer of data between the registers, and the operations performed on that data are typically specified using Hardware Description Languages (HDLs) such as Verilog or Verilog HDL (VHDL). The RTL may represent a behavior of individual registers within the system. The registers are like memory units/flip-flops used to store the data temporarily. The RTL may be used to transfer the data between the registers. The data transmission may occur in response to control signals or clock pulses. The RTL may perform various operations on the data as the data transfers between the registers. The various operations may include, but not limited to, arithmetic operations, logical operations, and shift operations. The arithmetic operations may include addition, subtraction, multiplication, and the like. The logical operations may include AND, OR, XOR, and the like. The shift operations may include left shift, right shift, and the like.

The RTL designs may synchronize to the clock signals. For example, the RTL designs may include sequential logic elements such as flip-flops, registers, and the like. The logic elements may store the data and change a state of the data based on a clock signal. For example, the rising edge or falling edge of the clock signal may trigger the transfer of data into the logic elements or out of the logic elements. The RTL may serve as an intermediate level of abstraction between a high-level performance of the system and a low-level performance of the system, thereby allowing designers to specify the functionality of the system, and providing an easy way for designers to verify and validate the performance of the system before implementation.

In the present disclosure, the method may include tiling the RTL design which may involve segregating an entire design of the system into smaller modular components such as tiles. Each tile may represent a specific functionality or component within the RTL design. Additionally, as per the system requirements, more tiles may be added or replicated as needed. In exemplary embodiments, the tiled RTL design may enable designers to focus on developing individual tiles with well-defined functionalities. The tiled RTL designs may be reused across different systems, thereby reducing development time and effort on creating new system(s). In exemplary embodiments, by designing and verifying the smaller tiles independently, the verification process becomes more manageable for the designers. In exemplary embodiments, the tiled RTL designs may facilitate hierarchical design methodologies, where complex systems are built from simpler, reusable components. The hierarchical structure may be used to identify and manage components within the design. In example scenarios, a Graphical Processing Unit (GPU) may be divided into multiple functional units (e.g., the tiles), and each functional unit may be responsible for specific tasks such as vertex processing, geometry shading, pixel shading, and rasterization. When the complexity of graphics rendering increases or new rendering techniques are introduced, additional tiles may be added, or existing tiles may be replicated to meet the performance requirements. Each tile such as the vertex processing or pixel shading may be designed and verified independently. Moreover, the tiles may be reused in different GPU designs or integrated into other digital system(s).

FIG. 4 illustrates a flowchart of a method 400 for generating a tiled RTL design, in accordance with an example implementation.

Referring to FIG. 4, in an embodiment, for generating the tiled RTL design, at step 402, the method 400 may include determining a number of identification bits (e.g., a width of bits) to identify each RTL instance with local bits corresponding to a local identifier, context bits corresponding to a context identifier, and parent bits corresponding to a parent identifier. At step 404, the method 400 may include identifying first groups of edges of a graph representation of the RTL design to assign the local identifier uniquely by edge and second groups of edges of the graph representation of the RTL design to assign the context identifier uniquely by group. At step 406, the method 400 may include generating the tiled RTL design with the parent bits coming from a boundary port of the RTL design, and the local bits and the context bits provided to the child RTL instances as assigned. In exemplary embodiments, for determining the number of identification bits for each RTL instance, the method 400 may consider three types of bits such as the local bits, the context bits, and the parent bits. In an embodiment, the local bits may uniquely identify each instance within a module to distinguish different instances at a local level. In an embodiment, the context bits may provide additional context information about the role or position of the instances within the larger design, thereby facilitating the determination of instance identification, allowing varied behavior of those instances within the system. In an embodiment, the parent bits may identify the parent component or module that contains the instance, establishing the hierarchical relationship within the design. For example, in an example scenario, the design of a digital processor may include various modules such as an Arithmetic Logic Unit (ALU), a control unit, and registers. Each module may include multiple instances and the method 400 may uniquely identify each instance within the digital processor design hierarchy for the purpose of those instances having instance-specific configuration.

In an embodiment, the local bits may uniquely identify each of multiple instances within a single parent module, distinguishing instances at a local level. For example, if there are three instances of a component design within a parent module, the instances may be represented using binary numbers such as “00,” “01,” and “10.” In an embodiment, the parent bits may identify the parent component or module that contains the instance, establishing the hierarchical relationship within the design. For example, if the module is incorporated within another module, then the relationship between the modules may be represented using specific bit positions, where each bit position may be used to differentiate instances at each hierarchical level. The bit positions may take binary values such as “0” or “1”, or in the case of multi-bit configurations, values such as “00”, “01” and so on, to uniquely identify and distinguish instances within the modular structure. The first level may represent a top tier of the hierarchy, while the second level may represent the tier immediately below the top tier. The levels may organize the design hierarchy and establish the relationships between different components or modules within the system. In an embodiment, the local and parent bits may not suffice to uniquely identify an instance. The addition of context bits may disambiguate the combination of local and parent bits, facilitating the determination of functionality within the system. For example, if a component, C, is instantiated once within different parents, call them A and B. Since there’s only one instance of C inside A, no local id bits are needed, and similar for C within B. There is likely to be an instance of A with id 0 as well as an instance of B with id 0. Without context bits, A.C would get the same id as B.C, but these should get unique id values to drive the strap compression table. In this case, assigning one instance context bit “0” and the other instance context bit “1”, allows each instance to have a unique ID.

In exemplary embodiments, to determine the number of identification bits to identify each RTL instance with the local bits, the context bits, and the parent bits, the method 400 may include setting zero as the number of identification bits for each RTL instance being a root in the graph representation. In an embodiment, in the process of determining the number of identification bits for each RTL instance within the design, a specific condition may be applied to instances that are considered roots in the graph representation. When the RTL instance is identified as a root in the graph representation, the zero identification bits may be assigned to that instance, indicating that the root instances are at the top level of the design hierarchy, do not have any parent instances, and do not require any additional bits for identification. For example, a digital circuit may include a main module consisting of arithmetic units and display controllers. The main module may serve as the root node in the design hierarchy. As a result, the main module may be allocated zero identification bits, as the main module does not have a parent node within the digital circuit. This approach may simplify the identification process by indicating that instances positioned at the top level of the hierarchy do not need to encode parent or context information since the instances are not contained within any other module or component. Instead, the instances are the highest-level elements within the design structure.

As an example, in the digital system, if a Central Processing Unit (CPU) module is the root node and the CPU does not have the parent node, then the method 400 may include assigning zero identification bits to the CPU module. If the ALU module and the memory controller module are the child nodes of the CPU module, each child node needs identification bits for local, context, and parent identifiers. If 2 bits are assigned for local identification, 1 bit is assigned for context identification, and 2 bits are assigned for parent identification, then the local bits of the ALU may be represented as “00,” the context bits of the ALU may be represented as “1,” and the parent bits of the ALU may be represented as “00” (e.g., the CPU). Similarly, the local bits of the memory controller module may be represented as “01,” the context bits of the memory controller module may be represented as “1,” and the parent bits of the memory controller module may be represented as “00” (e.g., the CPU). In this example, since the CPU module is the root node and has no parent node, the bits are not allocated for the CPU, hence the CPU may be set as zero.

In some examples, in a NoC design, where a router may serve as the root node of the digital system; since the router acts as the central communication hub without any parent node, zero identification bits are assigned to the router, represented as “00.” If there are child nodes connected to the router (e.g., root node), such as processing cores, memory controllers, and peripheral interfaces, each child node requires identification bits for local identification, context identification, and parent identification. In this example, 2 bits may be assigned for local identification, 1 bit may be assigned for context identification, and 2 bits may be assigned for parent identification. For example, if the router is connected to the ALU module and the memory controller module, the local bits of the ALU may be represented as “00,” the context bits may be represented as “1,” and the parent bits may be represented as “00” (referring to the root router). Similarly, the local bits of the memory controller module may be represented as “01,” the context bits may be represented as “1,” and the parent bits may be represented as “00” (also referring to the root router). In this scenario, no bits are allocated to the router, and the router is set to zero, as the router does not require identification bits. This approach may ensure that each component within the NoC design hierarchy is uniquely identified and efficiently managed, facilitating optimized communication and resource utilization across the network.

In an embodiment, in the process of determining the number of identification bits for each RTL instance, including the local bits, the context bits, and the parent bits, the method 400 may include, from a set of multiple instantiated parent nodes of a node in the graph representation of the RTL design, setting a sum of, a maximum of, the number of identification bits of a parent node from the set plus another number of the local bits derived from a third number of instantiations of a child node in the parent node from the set, a minimum number of bits to represent all instantiations of the RTL design, and a minimum number of bits to represent a total number of parent nodes of the node. In exemplary embodiments, to determine the number of identification bits for each RTL instance, the method 400 may include examining the graph representation of the design. Specifically, the method 400 may include considering a set of parent nodes that are instantiated multiple times within the design. From the set of parent nodes, the number of identification bits may be determined for each instance.

In some embodiments, the method 400 may include determining the maximum number of identification bits for each instance. To determine the maximum number of identification bits for each instance, the method 400 may include considering the number of identification bits required for the parent node from the set of multiple instantiated parent nodes, ensuring that each instance can be uniquely identified within the parent node. Additionally, the method 400 may include considering a number of the local bits derived from the third number of instantiations of the child node within the parent node. The local bits may provide context specific to each instance within an immediate environment. For example, in the digital system, the CPU module contains multiple instances of the ALU module. Each ALU instance may need to be uniquely identified within the CPU module. Therefore, identification bits may be allocated based on both the CPU module (e.g., the parent node) and the ALU instances (e.g., the child node) within the CPU module.

For example, in the digital system with the CPU module (e.g., the parent node) that includes multiple instances of the ALU module (e.g., the child node), each ALU instance needs to be uniquely identified within the CPU module. The CPU module itself needs to be uniquely identified within the overall design assembly. Therefore, the method 400 may include calculating the requirement of the number of identification bits and assigning the identifiers to the parent node and the child node. The identifier assigned to the CPU module (e.g., the parent node) may be “01.” The identifiers assigned to the ALU instances (e.g., the child node) within the CPU module may be “001,” “010,” “011,” and so on. Additionally, the parent bit may be represented as zero to identify the CPU module, since the CPU module is the top-level module.

In some examples, where the router in the NoC architecture may function as the child node within the digital system, the router may be connected to the parent node, such as a processing core or a memory unit, and requires identification bits for precise routing and management within the NoC framework. To make accurate routing and communication, the method 400 may allocate 3 bits for local identification, 2 bits for context identification, and 3 bits for parent identification. For example, if the parent node is the processing core, the local bits of the router may be assigned as “101” to uniquely identify the router within the NoC design. The context bits may be designated as “10” to provide contextual information within the broader system architecture, and the parent bits may be set to “011” to denote the parent node. This approach may ensure that each instance of the router is uniquely identified and distinguished within the NoC design hierarchy, facilitating efficient routing and communication between different components of the digital system.

In an embodiment, the minimum number of bits is calculated to represent all ALU instances. In this example, at least 3 bits are needed to cover all possible ALU instances, as 23 equals 8, which includes all combinations. Further, the minimum number of bits is determined to represent the total number of parent nodes. In this case, with only one parent node (e.g., the CPU module), the ALU instance can be represented with 2 bits (01). Therefore, for each ALU instance, 3 bits are allocated for local identification (e.g., 001, 010, 011, and so on), 0 bits for context identification (as ALU instances have no child nodes), and 2 bits for parent identification (e.g., identifying the CPU module). Thus, the total number of identification bits for each ALU instance is calculated as the sum of local, context, and parent bits, resulting in 5 bits. The allocation of identification bits may ensure efficient and accurate identification of each instance within the digital system, facilitating seamless operation and management.

In an embodiment, the method 400 may include determining the minimum number of bits necessary to represent all instantiations of the RTL design to ensure that each instance may be assigned enough bits to accommodate all possible combinations of instances within the design. For example, the CPU module may contain not only ALUs but also memory units, control units, and other components. Each of the components may have multiple instances within the CPU module. Within the CPU module, there may be multiple instances of the ALUs responsible for performing arithmetic and logic operations. Additionally, there may be several memory units, such as registers and caches, used for storing data temporarily during computations. Furthermore, the CPU module may include control units responsible for managing the flow of instructions and coordinating the operation of different components. Each component instance must be uniquely identified within the CPU module, ensuring that no two instances are identified incorrectly with respect to each other. Therefore, the method 400 may include allocating sufficient identification bits to cover all possible combinations of the components within the CPU module to ensure that each instance, whether the ALU, the memory unit, or the control unit, are accurately identified within the overall architecture of the CPU module.

In an embodiment, the method 400 may include assigning unused local identifiers having the number of identification bits to instantiations of child nodes of the graph representation of the RTL design having parent nodes without multiple instantiations. In exemplary embodiments, initially, child nodes may be identified within the graph representation, representing instances of the components or the modules within the design. Subsequently, the parent nodes lacking multiple instantiations are determined within the graph representation. The parent nodes may contain child nodes but are not instantiated multiple times within the design. Then, for each parent node without multiple instantiations, unused local identifiers may be assigned to its child nodes. The local identifiers may uniquely identify each child node instance within the scope of its parent node. For example, within the CPU design, various modules and components are represented as child nodes in the graph representation. These child nodes may include units such as ALU, control unit, memory interface, and Input/Output (I/O) controller. Among the child nodes, certain modules within the CPU, such as the ALU or the control unit, may not have multiple instantiations. These modules may act as single units within the CPU design and are responsible for specific tasks such as arithmetic operations or instruction decoding. For each of these modules without multiple instantiations, unused local identifiers are assigned to their respective child nodes. For example, within the ALU module, different components such as adders, multipliers, and shifters may require unique local identifiers. By assigning unused local identifiers to child nodes within these modules, conflicts are avoided, and each component can be uniquely identified within its parent node without needing a global identifier. For components with a single instantiation, the strap values can be determined without requiring a unique global ID. However, for tiled components that have instances in non-tiled parents, a unique, independent ID can be assigned directly. Complex ID assignment is primarily necessary when there are multiple levels of tiling, as each instance may need a distinct identifier to prevent conflicts across nested levels. For example, the unique local identifier for the adder may be “001,” for the multiplier may be “010,” and for the shifter may be “011.”In an embodiment, the method 400 may include identifying the first groups of edges within the graph representation of the RTL design. These groups may be examined to assign the local identifier uniquely by the edge. Each edge may represent a specific connection between two nodes, and the unique local identifier may be assigned to differentiate edges. Similarly, the method 400 may examine the second groups of edges within the graph representation of the RTL design. These edges may be analyzed to assign the context identifier uniquely by the group. Instead of individual edges, this step may consider groups of edges, possibly representing larger functional units or modules within the design. The unique context identifier is assigned to each group. In an embodiment, the local identifiers may be assigned uniquely to each edge in the first groups of edges to ensure that each connection between the nodes in the design is uniquely identified.

In an embodiment, the first group may represent a set of edges within the graph representation of the RTL design. The edges may be examined individually to assign unique local identifiers. For example, in the digital system, each connection between two logic gates represents the edge. The set of edges connecting the ALU to different registers in the CPU may be considered as the first group. In an embodiment, the second group may consist of sets of edges within the graph representation. For example, in the digital system, the connection between different functional units, such as the ALU, the memory unit, and the input/output controllers may form the second group. In an embodiment, the sub-group may be a subset of edges within the second group. The sub-group may represent a more granular level of organization within the larger group of edges. For example, within the second group, depicting connections between the ALU and the memory unit, sub-groups may define specific data paths or control signals, such as the data bus, address bus, and control lines.

In an embodiment, the identifier may be a unique label or name assigned to an element within the RTL design, such as the node or the edge. The identifiers may be used to differentiate and identify specific elements. For example, in the graph representation of the digital system, each edge may be assigned a unique identifier, such as “E1,” “E2,” etc., to distinguish between different connections. In an embodiment, the local identifier may be assigned to each edge in the first group. The local identifier may differentiate between individual connections within the design. For example, in the digital system, each connection between the ALU and the register may be assigned with local identifier such as “1,” “2,” “3,” and so on. In an embodiment, the context identifier may be assigned to each group or sub-group of edges in the second group. The context identifier may provide the context information or grouping information for a set of connections. For example, in the digital system, the connections between the ALU and the memory unit may be assigned with the context identifier “A,” while the connections between the ALU and input/output controllers may be assigned with “B.” In an embodiment, the edge may represent a connection between two nodes in the graph representation of the RTL design. In the digital system, these nodes may be logic gates, registers, or other functional units. For example, in the digital system, the edge connects the output of an AND gate to the input of an OR gate, representing the flow of data from one gate to another gate.

In an embodiment, the context identifier may be assigned uniquely to groups of edges in the second group of edges. These groups of edges may represent larger functional units or modules within the design. For example, in a processor design, groups of edges representing the connections between the ALU and the memory controller may be assigned a unique context identifier. This identifier distinguishes the connections related to memory operations from those related to arithmetic operations, providing a higher-level context within the design. Therefore, the method 400 may ensure that each connection and group of connections within the RTL design is uniquely identified by local and context identifiers, respectively.

In an embodiment, the method 400 may include configuring the tiled RTL design with the parent identifier provided to the parent bits, and the local identifier to the local bits, and the context identifier to the context bits according to the assignment. Each instance within the RTL design is assigned identification bits, including parent bits to identify the parent component or module containing the instance, the local bits to uniquely identify the instance within its immediate module, and the context bits to provide additional context information about the role or position of the instance within the larger design hierarchy. For example, within the design of the digital system, there are multiple instances of a cache module arranged in a grid-like pattern. Each instance of the cache module may require identification bits to distinguish the particular cache module from other instances within the design. Thee identification bits may include parent bits to identify the larger module containing the cache instance (e.g., the CPU), the local bits to uniquely identify the cache instance within its module, and the context bits to provide context information about the role (e.g., instruction cache, data cache) of the cache instance within the CPU. Once the identification bits are assigned, the tiled RTL design may be configured accordingly.

In an embodiment, the parent identifiers may be provided to the parent bits, the local identifiers may be provided to the local bits, and the context identifiers may be provided to the context bits, following the assignment process. In this example, the parent identifiers, the local identifiers, and the context identifiers may be configured based on the assignment of identification bits to each cache instance. For example, if a particular cache instance is identified by the parent bits “001” (indicating it belongs to the CPU), the local bits “101” (uniquely identifying it within the cache module), and the context bits “010” (representing it as an instruction cache), these identifiers may be configured accordingly in the tiled RTL design. Once all instances within the tiled RTL design are configured with their respective identification bits, the design may be ready for further implementation, simulation, or synthesis stages in the digital design flow.

In an embodiment, the tiled design may include multiple instances of RTL modules. Each tile may contain one or more RTL modules, and these tiles may be interconnected to form the complete design. In an embodiment, the parent bits for each RTL instance may be sourced from a boundary port of the RTL design. The boundary port may be an interface through which the RTL design communicates with external components, such as other modules or the system. The parent bits may provide information about the parent module or tile that contains each RTL instance. For example, in generating the tiled RTL design for the CPU, the method 400 may include organizing multiple instances of RTL modules into a tiled structure. Each module may represent different functional units of the CPU, such as the ALUs, the control units, and memory interfaces.

In an embodiment, the parent bits for each RTL instance may be sourced from the boundary port of the CPU design. The boundary port may act as the interface through which the CPU communicates with other components or modules in the system. The parent bits may provide information about the parent module or tile containing each RTL instance. For example, in the tiled CPU design, the parent bits for each RTL instance may originate from the boundary port of the CPU tile. These bits may indicate which CPU module or tile contains each RTL instance.

In an embodiment, the local bits and the context bits may be assigned to each child RTL instance within the tiled design. The local bits and the context bits may be provided to the child RTL instances based on their assigned values. The assignment of the local bits and the context bits may ensure that each RTL instance may be uniquely identified within the module and provide context information for the operation. For example, in the tiled CPU design, each instance of the ALU module may receive the local bits to distinguish between different ALUs within the module. The context bits may indicate the specific operation (e.g., addition, subtraction, bitwise operations) performed by each ALU instance. As per these examples, the method may involve generating the tiled RTL design for the CPU, sourcing the parent bits from the boundary port, and assigning the local bits and the context bits to the child RTL instances, thereby enhancing the proper identification within the CPU architecture.

In an embodiment, the method 400 may include a strap compression technique that provides an efficient solution for configuring hardware components within the system. Unlike traditional methods, which allocate separate hardware for each possible configuration, the strap compression techniques may enable components to be designed in a way that they can be dynamically configured using predefined strap values and control bits. Instead of dedicating distinct circuitry for each configuration, a single set of circuitries can adapt to different configurations based on the applied strap values and control bits. Additionally, within the method 400, there may be a process implemented for selecting a specific configuration among the multiple configurations available. The selection process may involve the utilization of a multiplexer which is an electronic device capable of selecting one of several input signals and then transmitting it to a single output line, based on received control signals. In an embodiment, the multiplexer may provide dynamic routing of data or control signals, enabling the system to choose the appropriate configuration from a set of available options. The input signals to the multiplexer may include various configuration parameters or the control bits, thereby indicating the specific configuration to be activated.

In an embodiment, the method 400 may include configuring each sub-design of the tiled RTL design with the multiplexer configured to select the configuration of each sub-design. Additionally, the method 400 may include driving the multiplexer to select a configuration from the input of the identification bits of each RTL instance. For example, the CPU design may include multiple functional units, including the ALUs and the memory controllers. Each functional unit may be represented as a sub-design within the tiled RTL architecture. Within each sub-design, the multiplexer may be configured to allow for dynamic selection of different configurations or operations. For example, the ALU sub-design may have multiplexers configured to select between different arithmetic operations such as addition, subtraction, multiplication, and bitwise operations. These multiplexers may enable the execution of various operations within each functional unit based on the input data and control signals. For example, if a specific ALU instance within the CPU design needs to perform an addition operation, the appropriate configuration may be selected by controlling the multiplexer associated with that ALU instance using the identification bits. The ALU then performs the addition operation on the input operands provided thereto, producing the result as output. Similarly, other functional units such as the memory controller may perform operations such as read, write, or fetch instructions from memory based on the selected configuration.

In exemplary embodiments, the dynamic selection of configurations through multiplexers allows for efficient utilization of resources within the CPU design. For example, depending on the computational requirements of a particular task, different ALU instances may be configured to perform different operations simultaneously. The ability to perform parallel operations may enhance the overall performance and throughput of the CPU design. In some example scenarios, where the CPU is executing a program that involves both arithmetic and logic operations, multiple ALU instances within the CPU may be configured with the multiplexers to perform these operations concurrently. While one ALU instance is performing addition, another ALU instance may be performing bitwise AND operations. The selection of configurations for each ALU instance may be dynamically controlled based on the specific operations required by the program instructions and the data being processed. Therefore, configuring multiplexers with each functional unit enables dynamic selection of configuration, thereby enhancing the efficient utilization of resources and the overall performance of the CPU design.

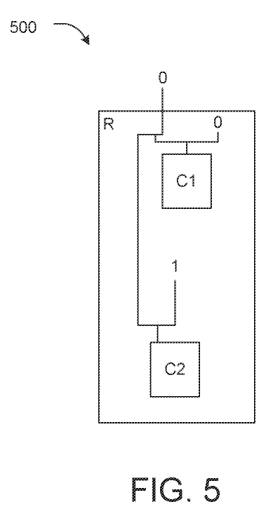

FIG. 5 illustrates a schematic representation 500 of a configuration mechanism, in accordance with an example implementation.

Referring to FIG. 5, the present disclosure may represent a mixed approach to bit assignment, where certain configuration bits (0) are defined at a higher level region (R), while other bits (0) are set locally within each instance (C1 and C2). The intermediate approach may enable each instance (C1 and C2) to maintain a unique ID and specific configuration without requiring an excessive number of strap bits to be brought to the boundary, thereby simplifying the design and reducing configuration overhead. However, a two-part scheme, involving just two layers or levels of configuration, may not provide adequate flexibility for managing these instances (C1 and C2) effectively. Instead, a “three-part scheme” introduces an additional level or mechanism for configuration, providing more granular control over the unique settings of each instance (C1 and C2). Additionally, the enhancement may allow for finer adjustments and improved management of configuration parameters. Therefore, the present disclosure represents the constraints of the current configuration process, particularly when handling multiple instances that require distinct configurations. Additionally, a multi-layered configuration scheme is introduced to enhance instance management, reduce manual intervention, and limit the strap bits exposed at the design boundary.

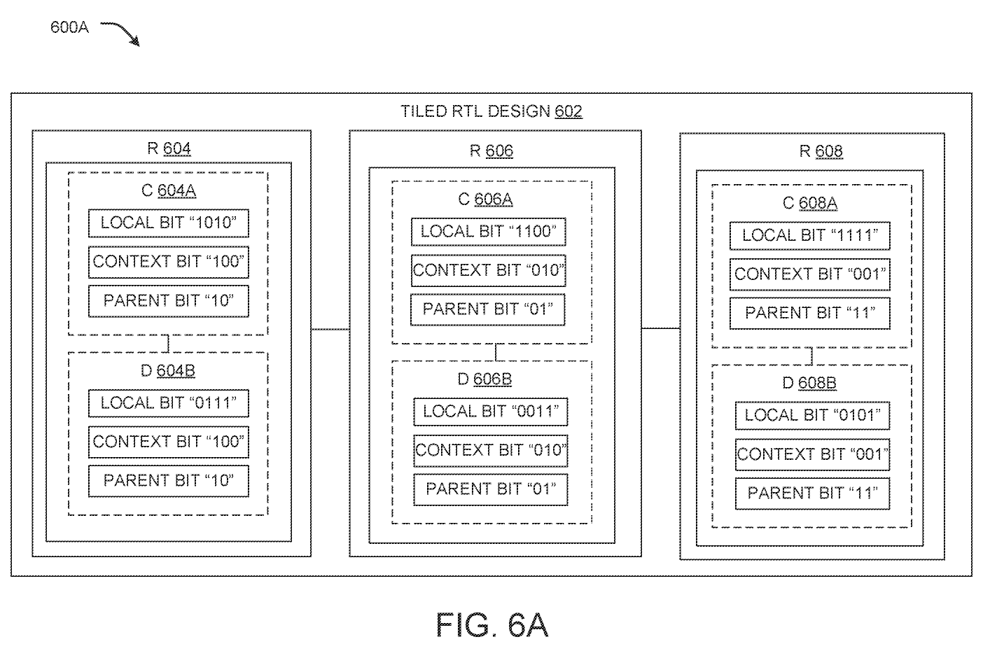

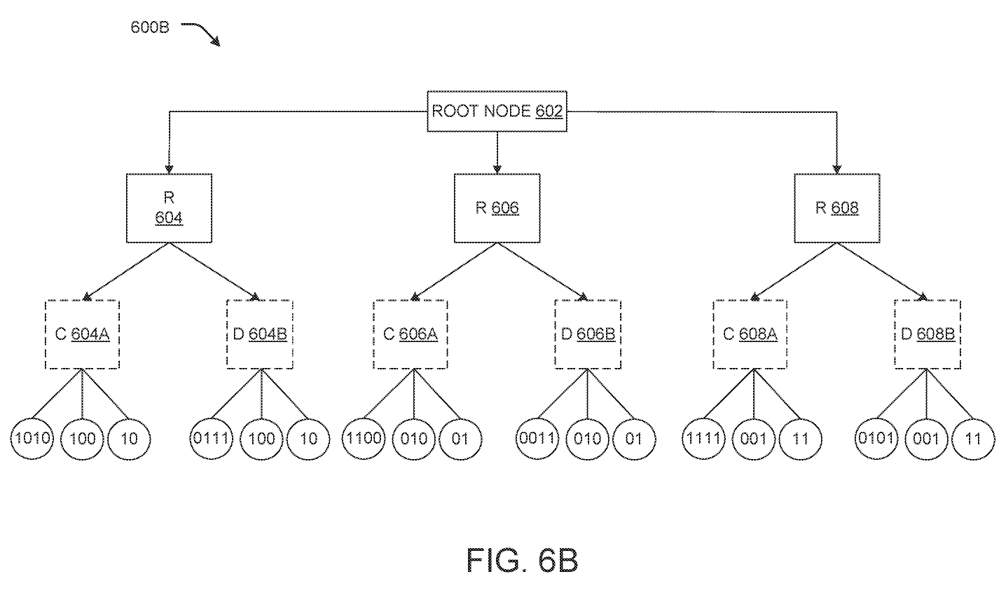

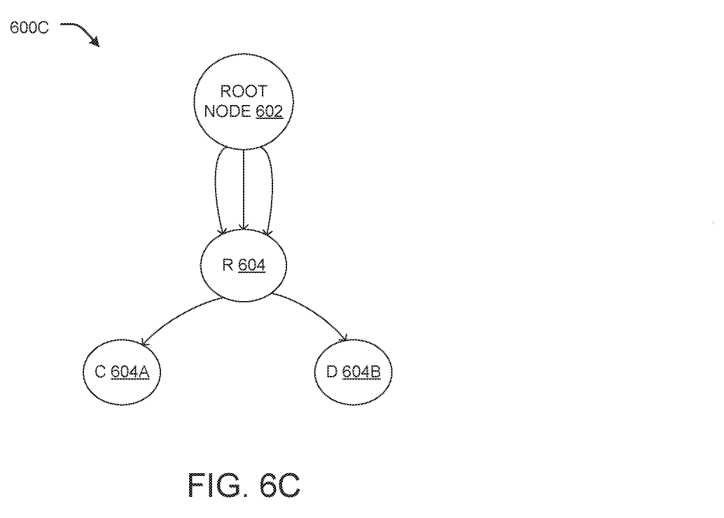

FIG. 6A illustrates a schematic representation 600A of a tiled RTL design, in accordance with an example implementation.

Referring to FIG. 6A, in the tiled RTL design 602, there are three parent nodes (R) 604, 606, and 608. Within each parent node (R) 604, 606, and 608, there are two child nodes C and D. For example, the R 604 includes C 604A and D 604B, the R 606 includes C 606A and D 606B, and the R 608 includes C 608A and D 608B. The child nodes may represent specific instances or configurations of components within their respective parent nodes. Each child node may be characterized by the local bits, the context bits, and the parent bits, which uniquely identify the instance within the parent node and its relationship to the overall design hierarchy. The local bits associated with each child node within the parent node correspond to a local identifier, distinguishing it from other instances within the same parent node. The context bits may be used to uniquely identify each child node group within the parent node, facilitating organization and management within the design. The parent bits may provide information about the hierarchical relationship of the child node within the overall design structure.

In some examples, considering that the tiled RTL design 602 is the NoC architecture, where the routers may act as the child nodes within the hierarchical structure to efficiently manage data flow. The parent node may be a system-on-chip (SoC) design. Within this SoC design, the NoC may include parent nodes representing different regions of the chip, such as processing cores, memory units, and peripheral controllers. Each parent node may perform specific functionalities within the system. For example, within the NoC parent node (e.g., the processing cores), the child nodes (e.g., the routers) may route data between different cores and peripherals. Each router instance may require identification bits for precise routing and management within the NoC architecture. For example, 3 bits may be allocated for local identification, 2 bits for context identification, and 1 bit for parent identification to ensure accurate routing and communication. If the router instance within the NoC is configured to handle data between two processing cores, the router may be identified by local bits “1010” to distinguish it from other routers. The context bits may be set to “100” to indicate their role within the NoC, while the parent bit may be “10” to denote the parent node representing the processing cores. Similarly, other child nodes within the NoC, such as routers managing communication between memory units or peripherals, may also be assigned unique identification bits based on their specific roles and connections within the system. By assigning the local bits, the context bits, and the parent bits to each instance of the router, efficient data management and routing are facilitated within the NoC architecture.

In some examples, considering that the tiled RTL design 602 is the tiled CPU design that includes the hierarchical structure where various functional units are organized into parent nodes and child nodes to facilitate efficient data processing, each parent node represents a major component such as the ALU (e.g., the R 604), the control unit (e.g., the R 606), and the memory interface (e.g., the R 608). These R 604, 606, and 608 may serve as the primary building blocks of the CPU architecture, each responsible for specific operations or functionalities. In an embodiment, within each parent node, there are child nodes representing specific instances or configurations of the functional units. For example, within the ALU (e.g., parent node 604), child nodes (C) 604A and (D) 604B may include individual operations like addition, subtraction, and bitwise logical operations. In the control unit (e.g., R 606), C 606A and D 606B may represent different stages of instruction execution, such as instruction fetch, decode, and execute. Similarly, in the memory interface (e.g., the R 608), C 608A and D 608B may include individual operations like read data and write data. In this example, the local bits, the context bits, and the parent bits are assigned to each instance of the child nodes. In FIG. 6A, within the ALU (e.g., 604), if the C 604A is configured to perform addition operation, the C 604A may be identified by local bits “1010,” and if the D 604B is configured to perform subtraction operation, the D 604B may be identified by local bits “0111”. In the control unit (e.g., 606), the C 606A has local bits “1100” with respect to the operation of the instruction fetch, and D 606B has local bits “0011” with respect to the decode operation. Similarly, in the memory interface (e.g., 608), the C 608A has local bits “1111” with respect to the operation of the write data and D 608B has local bits “0101” with respect to the operation of the read data.

Additionally, in the ALU (e.g., 604), both C 604A and D 604B may share context bits “100”, indicating their association within the same context. In the control unit (e.g., 606), both C 606A and D 606B may share context bits “010”. Similarly, in the memory interface (e.g., 608), the C 608A and the D 608B may have context bits “001”. Furthermore, the C 604A and the D 604B within the ALU (e.g., 604) may have parent bits set to “10”. The C 606A and 606B within the control unit (e.g., 606) may have parent bits set to “01”. Similarly, the C 608A and the D 608B within the memory interface 608 may have parent bits set to “11”.

In some example embodiments, the tiled CPU (e.g., 602) may be the parent node for all three R 604, 406, and 608. The tiled CPU (e.g., 602) may function as a root node of the hierarchy, encapsulating all other components within the CPU design. As the root node, the tiled CPU (e.g., 602) may be configured to set the number of identification bits to “0” for its instances, as the tiled CPU (e.g., 602) represents the highest level of abstraction in the design.

FIG. 6B illustrates a hierarchical RTL design 600B, in accordance with an example implementation.

Continuing with the example representation of FIG. 6A, in the hierarchical representation of FIG. 6B, the root node may branch out into parent nodes. Each parent node has two child nodes, with assigned local bits, context bits, and parent bits for unique identification within the hierarchy. The parent bits may denote the level of hierarchy, with lower values indicating higher levels. It may be appreciated that there may be any number of child nodes of the parent node within the scope of the present disclosure.

FIG. 6C illustrates a Directed Acyclic Graph (DAG) representation C of the tiled RTL design, in accordance with an example implementation.

Referring to FIG. 6C, the root node 602 serving as the primary component, which includes multiple child nodes represented as C (604A) and D (606A)with specific multiplicities. For instance, a “multiplicity three child” may indicate three instances of a particular design. Within the structure, a region node (R) is defined, containing child nodes (e.g., C (604A) and D (606A)). Each region node (R) represents a distinct modular design, which may house multiple instances of other components. The system may be configured with the DAG structure rather than a traditional tree to facilitate the reuse of the same design node across multiple instances. Additionally, the DAG structure conserves memory and computational resources by preventing node duplication, while also supporting multiple edges leading to a single node for centralized control over each unique design component. Furthermore, configuration and data consistency may be managed on the edges (connections) rather than duplicating nodes, providing each child edge to receive a unique value and preserving consistent configuration across all instances.

Additionally, the edge-based configuration may avoid the risk of inconsistent values or configurations among child nodes, which the DAG structure prevents by enforcing single-node instances. Each design node is associated with a standardized wiring pattern, ensuring uniform functionality across the system, with compound labels on edges (e.g., instance IDs) adding specificity to the wiring patterns. By operating within the DAG structure, the system supports modular configurability, allowing a single design to be flexibly configured to meet instance-specific requirements without requiring multiple copies. Furthermore, the DAG structure enables efficient resource management, scalability, and consistent data across instances. Additionally, the DAG structure allows each node to be uniquely configured without redundancy, unlike a tree structure, which may complicate configuration and fail to handle compound edge effectively.

Referring to the labeling in FIGS. 6A, 6B and 6C, R 604 in FIG. 6C may correspond to the underlying design for R 604, 606, and 608 in FIGS. 6A and 6B. Similarly, C 604A in FIG. 6C may correspond to the C 604A, 606A, and 608A in FIGS. 6A and 6B, while D 606A in FIG. 6C may correspond to the D 604B, 606B, and 608B in FIGS. 6A and 6B.

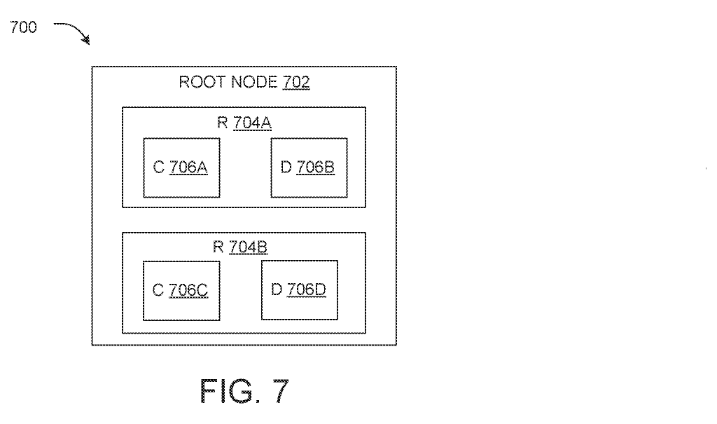

FIG. 7 illustrates a schematic representation 700 of the hierarchical RTL design structure, in accordance with an example implementation.

In an embodiment, the present disclosure provides a hierarchical system in the RTL design features multiple modules organized with defined relationships and configurations to facilitate complex functionality and maintain structural organization. Referring to FIG. 7, the hierarchy design may start with a root node 702, which may contain two instances of a sub R 704A and R 704B. Each R 704A and 704B, in turn, contains two instances of another sub-module C 706A, D 706B, C706C, and D 706D. Furthermore, the layered hierarchy may allow for modular reuse and organized complexity, with each level including repeating elements that contribute to the overall functionality of the hierarchy design.

In an embodiment, the layout of the design may be organized into specific regions assigned to each module. The sub-modules C 706A, D 706B, C 706C, and D 706D may define particular regions on a surface of the chip, while the sub-modules R 704A and R 704B may encompass both the regions and additional logic. In an embodiment, the root node 702 is positioned at the top of the hierarchy, represents either the entire chip or a major structural component that may integrate the sub-modules R 704A and R 704B and the sub-modules C 706A, D 706B, C 706C, and D 706D.

In an embodiment, the present disclosure provides strap wiring between sub-modules R 704A and R 704B and the sub-modules C 706A, D 706B, C 706C, and D 706D, which specifically refers to the wiring that may connect the sub-modules R 704A and R 704B and the sub-modules C 706A, D 706B, C 706C, and D 706D to facilitate configuration and control signal transmission. Unlike general wiring, the strap wiring may enable differentiated configuration for each module instance R 704A and R 704B and the C 706A, D 706B, C 706C, and D 706D, allowing distinct operational behavior across instances.

In an embodiment, each instance of the sub-module C 706A, D 706B, C 706C, and D 706D may include a compression table that may configure the sub-module based on the unique ID. Additionally, the compression table may take an ID as input and outputs specific configuration data, enabling each sub-module instance C 706A, D 706B, C 706C, and D 706D to operate according to individual settings. Although the structure of the compression table may remain consistent across instances, output values differ per module, ensuring customized functionality. In an embodiment, configuration settings may be propagated hierarchically, originating from higher levels such as the modules A 702 or the sub-module R 704A and R 704B. Furthermore, parent modules may pass specific configuration values down to child modules, enabling centralized control over the settings applied to each module instance R 704A and R 704B and the C 706A, D 706B, C 706C, and D 706D within the hierarchy.

In an embodiment, the entire chip structure may be generated by defining each module (root node 702, R 704A and R 704B, and C 706A, D 706B, C 706C, and D 706D) with instances and configurations while maintaining hierarchical relationships. This hierarchical design can be represented as a Directed Acyclic Graph (DAG), where the relationships between modules are depicted without cyclic dependencies. Each module instance is differentiated by unique ID bits, which include elements such as context ID, parent ID, local ID, and an identifier specific to the instance within its parent. This structured ID format ensures the precise identification of each module within the hierarchy, allowing accurate application of configurations to specific instances.

For example, in the hierarchical configuration, three modules, such as root node 702, R 704A and R 704B, and C 706A, D 706B, C 706C, and D 706D are defined with unique instance identifiers. The root node 702, positioned at the top level, exists as a single entity and does not require instance IDs. The sub-module R, which may have multiple instances, uses instance IDs to distinguish each occurrence, with parent ID bits associating each instance with root node 702. Each instance of R 704A and R 704B provides input to instances of C 706A, D 706B, C 706C, and D 706D.

In scenarios where R704A and R 704B include multiple instances, local bits are used to differentiate among the sub-modules C 706A, D 706B, C 706C, and D 706D. Similarly, for example, if another sub-module E, residing within R 704A and linked one-to-one with R 704A instances, utilizes the instance ID of R 704A for identification, the need for additional context bits is eliminated.

When multiple instances exist within a single parent context (for example, several instances of sub-modules C 706A, D 706B, C 706C, and D 706D within a single instance of sub-modules R 704A and R 704B), each instance of C is assigned a unique identifier using local bits specific to the instances within the parent R 704A and 704B. Combinations such as 00, 01, 10, and 11 are used to distinguish each instance of C 706A, D 706B, C 706C, and D 706D and eliminates the need for additional bits to identify the broader context, as the local bits suffice to uniquely identify each instance of C 706A, D 706B, C 706C, and D 706D within R 704A and R 704B.

In an embodiment, the configuration establishes unique identification for each sub-module within the hierarchical structure, maintaining clarity as the number of instances scales across levels. For instance, if R 704A and R 704B includes eight instances, three bits may be sufficient for identification, with further bits allocated to identify nested instances of C 706A, D 706B, C 706C, and D 706D within each instance of R 704A and R 704B. The hierarchical RTL design system may enable structured configuration propagation, ID-based differentiation, and efficient strap wiring between modules. The system provides a robust framework for complex chip design, with each module contributing to the overall functionality of the chip.

Referring to the labeling in FIGS. 6A, 6B and 7, the R 704A and 704B in FIG. 7 may correspond to the underlying design for R 604, 606, and 608 in FIGS. 6A and 6B. Similarly, the C 706A and C 706C in FIG. 7 may correspond to the C 604A, 606A, and 608A in FIGS. 6A and 6B, while D 706B and D 706D in FIG. 7 may correspond to the D 604B, 606B, and 608B in FIGS. 6A and 6B.

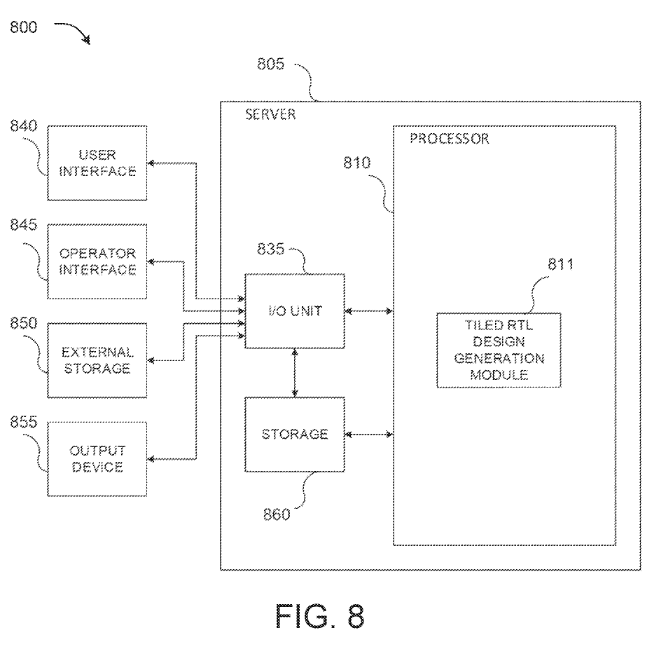

FIG. 8 illustrates an example computer system 800 on which example embodiments may be implemented. The computer system 800 includes a server 805 which may include an I/O unit 835, storage 860, and a processor 810 operable to execute one or more units as known to one of skill in the art. The term “computer-readable medium” as used herein refers to any medium that participates in providing instructions to processor 810 for execution, which may come in the form of computer-readable storage mediums, such as, but not limited to optical disks, magnetic disks, read-only memories, random access memories, solid state devices and drives, or any other types of tangible media suitable for storing electronic information, or computer-readable signal mediums, which can include transitory media such as carrier waves. The Input / Output (I/O) unit 835 processes input from user interfaces 840 and operator interfaces 845 which may utilize input devices such as a keyboard, mouse, touch device, or verbal command.

The server 805 may also be connected to an external storage 850, which can contain removable storage such as a portable hard drive, optical media (CD or DVD), disk media, or any other medium from which a computer can read executable code. The server may also be connected to an output device 855, such as a display to output data and other information to a user, as well as request additional information from a user. The connections from the server 805 to the user interface 840, the operator interface 845, the external storage 850, and the output device 855 may be via wireless protocols, such as the 802.11 standards, Bluetooth® or cellular protocols, or via physical transmission media, such as cables or fiber optics. The output device 855 may therefore further act as an input device for interacting with a user. The processor 810 may execute one or more modules. The processor 810 may include tiled RTL design generation module 811 that may be configured to determine a number of identification bits to identify each RTL instance with local bits corresponding to a local identifier, context bits corresponding to a context identifier, and parent bits corresponding to a parent identifier and identify first groups of edges of a graph representation of the RTL design to assign the local identifier uniquely by edge and second groups of edges of the graph representation of the RTL design to assign the context identifier uniquely by group. Further, the tiled RTL design generation module 811 may be configured to generate the tiled RTL design with the parent bits coming from a boundary port of the RTL design, and the local bits and the context bits provided to the child RTL instances as assigned.

Furthermore, some portions of the detailed description are presented in terms of algorithms and symbolic representations of operations within a computer. These algorithmic descriptions and symbolic representations are the means used by those skilled in the data processing arts to most effectively convey the essence of their innovations to others skilled in the art. An algorithm is a series of defined steps leading to a desired end state or result. In the example embodiments, the steps carried out require physical manipulations of tangible quantities for achieving a tangible result.

Moreover, other implementations of the example embodiments will be apparent to those skilled in the art from consideration of the specification and practice of the example embodiments disclosed herein. Various aspects and/or components of the described example embodiments may be used singly or in any combination. It is intended that the specification and examples be considered as examples, with a true scope and spirit of the embodiments being indicated by the following claims.

What is claimed is:

1. A method for generating a tiled Register Transfer Level (RTL) design, comprising:
determining a number of identification bits to identify each RTL instance with local bits corresponding to a local identifier, context bits corresponding to a context identifier, and parent bits corresponding to a parent identifier;
identifying first groups of edges of a graph representation of the RTL design to assign the local identifier uniquely by edge and second groups of edges of the graph representation of the RTL design to assign the context identifier uniquely by group; and
generating the tiled RTL design with the parent bits coming from a boundary port of the RTL design, and the local bits and the context bits provided to child RTL instances as assigned.

2. The method of claim 1, wherein the determining the number of identification bits to identify each RTL instance with the local bits, the context bits, and the parent bits comprises setting zero as the number of identification bits for each RTL instance being a root in the graph representation.

3. The method of claim 1, wherein the determining the number of identification bits to identify each RTL instance with the local bits, the context bits, and the parent bits comprises, from a set of multiple instantiated parent nodes of a node in the graph representation of the RTL design, setting a sum of:
a maximum of:
the number of identification bits of a parent node from the set plus another number of the local bits derived from a third number of instantiations of a child node in the parent node from the set;
a minimum number of bits to represent all instantiations of the RTL design; and
a minimum number of bits to represent a total number of parent nodes of the node.

4. The method of claim 1, further comprising assigning unused local identifiers having the number of identification bits to instantiations of child nodes of the graph representation of the RTL design having parent nodes without multiple instantiations.

5. The method of claim 1, further comprising configuring the tiled RTL design with the parent identifier provided to the parent bits, and the local identifier to the local bits and the context identifier to the context bits according to the assignment.

6. The method of claim 1, further comprising configuring each sub-design of the tiled RTL design with a multiplexer configured to select a configuration of each sub-design.

7. The method of claim 6, further comprising driving the multiplexer to select a configuration from input of the identification bits of each RTL instance.

8. A non-transitory computer readable medium, storing instructions for generating a tiled register transfer level (RTL) design, the instructions comprising:
determining a number of identification bits to identify each RTL instance with local bits corresponding to a local identifier, context bits corresponding to a context identifier, and parent bits corresponding to a parent identifier;
identifying first groups of edges of a graph representation of the RTL design to assign the local identifier uniquely by edge and second groups of edges of the graph representation of the RTL design to assign the context identifier uniquely by group; and
generating the tiled RTL design with the parent bits coming from a boundary port of the RTL design, and the local bits and the context bits provided to child RTL instances as assigned.

9. The non-transitory computer readable medium of claim 8, wherein the determining the number of identification bits to identify each RTL instance with the local bits, the context bits, and the parent bits comprises setting zero as the number of identification bits for each RTL instance being a root in the graph representation.

10. The non-transitory computer readable medium of claim 8, wherein the determining the number of identification bits to identify each RTL instance with the local bits, the context bits, and the parent bits comprises, from a set of multiple instantiated parent nodes of a node in the graph representation of the RTL design, setting a sum of:
a maximum of:
the number of identification bits of a parent node from the set plus another number of the local bits derived from a third number of instantiations of a child node in the parent node from the set;
a minimum number of bits to represent all instantiations of the RTL design; and
a minimum number of bits to represent a total number of parent nodes of the node.

11. The non-transitory computer readable medium of claim 8, the instructions further comprising assigning unused local identifiers having the number of identification bits to instantiations of child nodes of the graph representation of the RTL design having parent nodes without multiple instantiations.

12. The non-transitory computer readable medium of claim 8, the instructions further comprising configuring the tiled RTL design with the parent identifier provided to the parent bits, and the local identifier to the local bits and the context identifier to the context bits according to the assignment.

13. The non-transitory computer readable medium of claim 8, the instructions further comprising configuring each sub-design of the tiled RTL design with a multiplexer configured to select a configuration of each sub-design.

14. The non-transitory computer readable medium of claim 13, the instructions further comprising driving the multiplexer to select a configuration from input of the identification bits of each RTL instance.
